(19) United States
(12) Patent Application Publication
(10) Pub. No.: US 2006/0085705 A1
(43) Pub. Date: Apr. 20, 2006

(54) Memory circuit comprising an initialization unit, and method for optimizing data reception parameters in a memory controller

(76) Inventor: Andre Schaefer, Munchen (DE)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/240,334

(22) Filed: Sep. 30, 2005

(30) Foreign Application Priority Data
Sep. 30, 2004 (DE) 10 2004 047 663.2

(51) Int. Cl. G11C 29/00

(52) U.S. Cl. 714/718

(57) ABSTRACT

The invention relates to a memory circuit comprising a read only memory unit for providing a number of fixed programmed test data; comprising an initialization unit in order, in an initialization mode, to output the fixed programmed test data in a specific sequence to an output terminal.

### CROSS-REFERENCE TO RELATED APPLICATIONS

This application claims foreign priority benefits under 35 U.S.C. §119 to co-pending German patent application number DE 10 2004 047 663.2, filed 30 Sep. 2004. This related patent application is herein incorporated by reference in its entirety.

### BACKGROUND OF THE INVENTION

1. Field of the Invention

The invention relates to a memory circuit comprising an initialization unit, and to a method for optimizing data reception parameters in a memory controller.

2. Description of the Related Art

In order to optimize the data transfer from a memory component to a memory controller with regard to reception parameters such as set-up and hold times, it is possible, during an initialization phase, for test data to be transmitted from the memory component to the memory controller in order that the memory controller optimally sets set-up and hold times. This may be performed by a test data generator, for example, which, in the initialization phase, transmits a specific test pattern in the form of a sequence of test data bits to an output terminal. In this case, the test data are often generated with the aid of an LSSA shift register with suitable feedbacks, with the result that a pseudorandom bit sequence is obtained.

Modern memory components have to be able to transmit and receive data at increasingly higher frequencies. At the same time, however, the speed at which the test data are provided by a test data generator unit is highly limited on account of the technology that is usually used for a DRAM memory circuit. For example, only two or three metal layers are used for the integrated construction of DRAM circuits, while logic circuits use up to seven metal layers. This and other technological parameters considerably limit the processing speed of logic signals in an integrated DRAM memory circuit, so that the test data cannot be provided at a sufficient speed for transmission at an output terminal. Consequently, a test data generator unit for optimizing reception parameters in a memory controller, such as is known in other integrated logic circuits, cannot be used for memory circuits, in particular for DRAM memory circuits.

### SUMMARY OF THE INVENTION

One aspect of the present invention provides a memory circuit comprising an initialization unit which provides test data which can be used to optimize reception parameters in a circuit connected to the memory component, in particular in a memory controller.

Another aspect of the present invention provides a method for optimizing reception parameters which can be carried out with the aid of an integrated memory circuit.

A first aspect of the present invention provides a memory circuit having a read only memory unit for providing a number of fixed programmed test data. The memory circuit furthermore has an initialization unit, which is configured in order, in an initialization mode, to output the fixed programmed test data in a predetermined sequence to an output terminal.

According to the invention, the memory circuit has the advantage that in an initialization mode in which the intention is to optimize reception parameters for test data that are to be transferred from a memory circuit to a memory controller, the test data can be provided at a sufficient speed in order, at very high transfer rates between the memory controller and the memory circuit, to be able to determine the reception parameters under real-time conditions. In particular, the test data are, in this, case communicated to the memory controller with the transfer frequency that is customary for the transfer path between the memory controller and the memory component, with the result that the memory controller can optimize set-up and hold times of the input latches situated at its inputs. Set-up and hold times are usually optimized by means of delay elements which set a delay time in a suitable manner. According to the invention, the advantage of the memory circuit consists, in particular, of the fact that the read only memory unit does not generate the fixed programmed test data, representing a pseudorandom sequence of test data, during the initialization phase; rather the test data are already present in a hardwired fashion in the memory circuit and merely have to be connected to the output terminal in the specific sequence and the predetermined transfer frequency in order to transfer the test data to the memory controller. Simply connecting the test data provided to the output terminal requires much lower amplification, so that even in the case of a DRAM technology, with the aid of such an initialization unit, the test data can be generated in the specific sequence at a sufficient transfer speed for optimizing the reception parameters in the memory circuit.

It may be provided that driver circuits for driving a logic “0” or logic “1” in a manner corresponding to the corresponding bit of the test data are provided in the read only memory unit. In this case, the driver circuits are hardwired and provide a high level or a low level on a corresponding signal line in a manner corresponding to the bits of the test data.

The initialization unit may have a switching device and a control unit in order to connect the driver circuits via the switching device to the output terminal for outputting the test data in accordance with the specific sequence.

In accordance with a further embodiment of the invention, a plurality of output terminals may be provided, each of which is assigned a switching device, which are connected to the control unit. The control unit may be configured in such a way that the plurality of switching devices are switched in order to output the bits of the fixed programmed test data to the output terminals in a manner offset with respect to one another. In this way, it is possible to optimize a plurality of inputs in a memory controller with regard to their reception parameters, with the test data being transmitted to the output terminals in offset fashion in order to determine an influencing of the test data on the various output terminals, which are often arranged physically adjacent to one another, for various coupling scenarios. It is also possible as a result to choose the different levels of the output drivers of the DRAM memory circuit in such a way that the supply voltage source or the supply line situated in the memory circuit is loaded to a great extent, so that the voltage fluctuations on the corresponding supply line vary to the greatest possible extent during the initialization phase.

A further aspect of the present invention provides a method for optimizing data reception parameters in a memory controller. In this case, a number of fixed programmed test data are provided in a memory circuit. In an initialization mode the fixed programmed test data are output in a specific sequence to an output terminal. The memory controller sets at least one data reception parameter in an optimized manner with the aid of the test data.

A method according to the invention makes it possible to set the data reception parameters in a memory controller for a memory circuit, in particular for a DRAM memory circuit, during an initialization phase. During the initialization phase, test data are transmitted by the memory circuit at a transfer speed corresponding to the transfer speed of the memory data in a normal operation. At least one data reception parameter is thus set in an optimized manner in the memory controller. Since the generation of the test data in an integrated memory circuit that has been fabricated e.g., with the aid of a DRAM technology cannot be performed at a sufficient transfer speed, the invention provides for the test data in a fixed programmed fashion. As a result, the fixed programmed test data can be called up more rapidly and, during the initialization phase, the setting of the data reception parameters can be performed in the memory controller under real-time conditions.

It may be provided that in the initialization mode the bits of the fixed programmed test data are output in a specific sequence, in a manner offset with respect to one another, to a plurality of output terminals of the fixed programmed test data.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a block diagram of a memory circuit in accordance with a preferred embodiment of the invention;

FIG. 2 shows an initialization unit for a memory circuit in a preferred embodiment; and

FIG. 3 shows possible realization of the read only memory cells for the read only memory unit.

### DETAILED DESCRIPTION OF THE PREFERRED EMBODIMENT

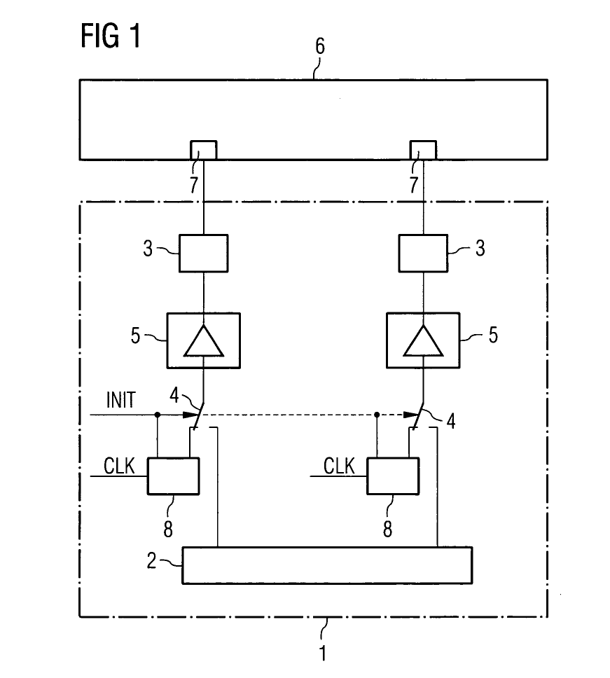

FIG. 1 shows a block diagram of a memory circuit 1 according to the invention. The memory circuit 1 comprises a logic and memory cell unit 2, which can be connected via corresponding data lines and assigned output drivers 5 to respective output terminals 3. For this purpose, the logic and memory cell unit 2 is connected via respectively assigned data switches 4 to the assigned output driver 5, the output of which is connected to the assigned output terminal 3. In normal operation, the data switches 4 are switched in such a way that data output by the logic and memory cell unit 2 are output to the output terminals 3 via the output drivers 5.

An initialization mode is adopted in order to optimize the data transfer path between the output terminals 3 and a memory controller that drives the memory component. In this case, input circuits 7 in a memory controller 6 are set optimally to receive data transmitted by the memory component. This is affected in a known manner. For this purpose, the input circuits 7 have, for example, delay elements (not shown) which can set a signal delay suitable for reception of the transmitted signals.

In the initialization phase, for the setting of the input circuits 7, a sequence of test data is transmitted on each bus line situated between the output terminal 3 of the memory circuit 1 and the input circuit 7 of the memory controller 6. The test data is used in accordance with the initialization mode in the memory controller 6 in order to set the input circuits 7. Particularly if the input circuits 7 have a latch, the reception parameters set-up time and hold time of the latch can be set, for example, with the aid of the sequence of test data. The initialization mode is indicated by signal INIT, which is either provided externally or generated internally in the memory circuit. The data switches 4 are switched in a manner dependent on the initialization signal INIT in such a way that the output terminals 3 are connected via the output drivers 5 to the logic and memory cell unit 2 during a normal operating mode and are connected via the output drivers 5 to an initialization unit 8 if the initialization signal indicates the initialization mode. The initialization unit 8 then outputs, in a manner triggered by the initialization signal INIT, a sequence of test data to the memory controller 6 via the output driver 5 and the output terminal 3. The initialization units 8 in each case obtain a clock signal CLK corresponding to the transfer frequency of the data in the normal operating mode, so that the input circuit 7 of the memory controller 6, for setting the reception parameters, obtains data at the transfer frequency at which it also obtains the data during the normal operating mode. However, other transfer frequencies may also be used for the transfer of the test data.

In the embodiment shown in FIG. 1, each of the output terminals 3 is assigned a dedicated initialization unit 8. However, it may also be provided that a single initialization unit 8 is assigned to all the output terminals 3 in order that essentially the same test data are made available to all the output terminals 3.

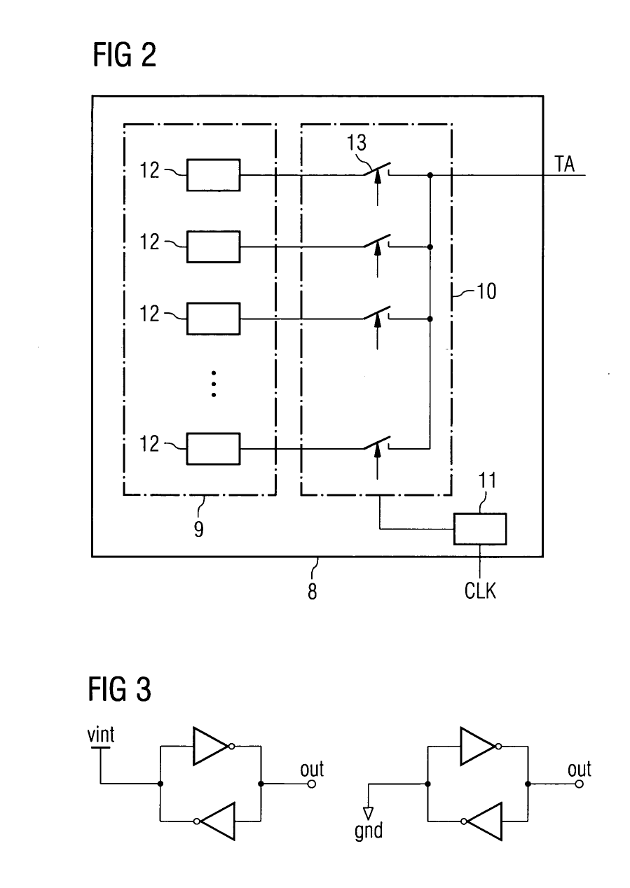

FIG. 2 illustrates an initialization unit 8 in greater detail. The initialization unit 8 has a read only memory unit 9 and a switching device 10, which is connected to a control unit 11. The read only memory unit 9 provides a number of bits of test data in read only memory cells 12. The read only memory cells 12 supply a high or low level, depending on what value the corresponding bit of the test data is intended to have. Each of the read only memory cells 12 is connected to the switching device 10, which has an assigned switch 13 for each of the read only memory cells 12. Via the switch, each of the read only memory cells 12 can be connected to a test data output TA of the initialization unit 8. The individual switches 13 of the switching device 10 are driven by a control unit 11 in such a way that only one of the read only memory cells 12 is connected to the test data output of the initialization unit 8. The control unit 11 drives the switches 13 in such a way that the latter are activated successively, so that the stored data values of the respective bit of the test data are successively connected to the test data output TA. The control unit 11 ensures that only one of the switches 13 is used in the switching device 10, so that two outputs of the read only memory cells 12 cannot be short-circuited with one another. In order to carry out the changing of the switching states of the switches 13 with the necessary frequency, the control unit 11 obtains a clock signal CLK via a clock input, which clock signal prescribes the speed at which the switches 13 are activated. The values set in accordance with a random distribution in the read only memory unit 9 thus prescribe a sequence of test data bits which is preferably pseudorandom and which is suitable for enabling the optimization of the reception parameters for the input circuit 7 in the memory controller 6.

FIG. 3 illustrates two examples of read only memory cells, the left-hand read only memory cell permanently outputting a low level, and the right-hand memory cell permanently outputting a high level. For this purpose, the read only memory cells have a negative feedback inverter pair, an input of one of the inverters of the inverter pair is connected to a high potential, preferably to an internal high supply voltage. It is possible for a low potential to be permanently tapped off at the output of this inverter. The opposite situation prevails in the case of the read only memory cell shown on the right; in that case, one of the inverters of the inverter pair is connected to a ground potential of the memory circuit, so that a high level can be permanently tapped off at its output.

In the embodiment of the invention as illustrated in FIG. 1, a dedicated initialization units with a dedicated read only memory units 9 is provided for each of the output terminals 3. In the case of a plurality of output terminals that are intended to be initialized simultaneously, the initialization units 8 may also be combined into a common initialization unit, which has only one read only memory 9. In this case, each of the output terminals 3 can transfer the same sequence of bits of the test data to the memory controller 6. In accordance with one embodiment of the invention, then, it is provided that the switching device 10 is configured in such a way as to implement the sequence of test data for each of the output terminals in a manner offset with respect to one another. In this case, given a chosen pseudorandom sequence of the bits of the test data, there is a shift by one or more bits with regard to one output, so that the same sequence of bits is not output simultaneously at any output and zeros and ones are distributed identically to zeros and ones output by the output terminals 3 simultaneously. In order to obtain a greatest possible loading of the supply potentials of the memory circuit, all the output terminals should be switched simultaneously to an identical potential, at least at one switching instant.

While the foregoing is directed to embodiments of the present invention, other and further embodiments of the invention may be devised without departing from the basic scope thereof, and the scope thereof is determined by the claims that follow.

What is claimed is:

1. A memory circuit, comprising:
a read only memory unit for providing a number of fixed programmed test data; and
an initialization unit configured to, in an initialization mode, output the fixed programmed test data in a specific sequence to an output terminal.

2. The memory circuit of claim 1, further comprising:
driver circuits for driving a logic “0” or logic “1” in a manner corresponding to the corresponding bit of the test data being provided in the read only memory unit.

3. The memory circuit of claim 2, wherein the initialization unit comprises:
a switching device; and
a control unit configured to connect the driver circuits via the switching device to the output terminal for outputting the test data in accordance with the specific sequence.

4. The memory circuit of claim 3, comprising:
a plurality of output terminals connected to the control unit, each of which is assigned a switching device.

5. The memory circuit of claim 4, wherein the control unit is configured to switch the plurality of switching devices in such a way that the bits of the fixed programmed test data are output to the output terminals in a manner offset with respect to one another.

6. The memory circuit of claim 1, wherein the number of fixed programmed test data comprises pseudorandom test data.

7. The memory circuit of claim 1, wherein the memory circuit comprises a dynamic random access memory (DRAM) circuit.

8. A method for optimizing data reception parameters in a memory controller, comprising:
providing a number of fixed programmed test data in a memory circuit; and
in an initialization mode, outputting the fixed programmed test data from the memory circuit in a specific sequence to an output terminal.

9. The method of claim 8, wherein:
in the initialization mode, the bits of the fixed programmed test data are output in a specific sequence, in a manner offset with respect to one another.

10. The method of claim 8, wherein the bits of the fixed programmed test data are output in a specific sequence to a plurality of output terminals.

11. The method of claim 8, wherein the fixed programmed test data comprises pseudorandom test data.

12. The method of claim 8, wherein the memory circuit is a dynamic random access memory (DRAM) circuit.

13. A memory system, comprising:
a memory controller; and
a memory circuit comprising a read only memory unit for providing a number of fixed programmed test data and an initialization unit configured to, in an initialization mode, output the fixed programmed test data to the memory controller in a specific sequence to an output terminal.

14. The system of claim 13, wherein the memory controller adjusts set-up and hold times of internal circuitry based on reception of the fixed programmed test data.

15. The system of claim 13, wherein the memory controller further comprising:
driver circuits for driving a logic “0” or logic “1” in a manner corresponding to the corresponding bit of the test data being provided in the read only memory unit.

16. The system of claim 15, wherein the initialization unit of the memory circuit comprises:
a switching device; and
a control unit configured to connect the driver circuits via the switching device to the output terminal for outputting the test data in accordance with the specific sequence.

17. The system of claim 16, wherein the memory circuit comprises:
a plurality of output terminals connected to the control unit, each of which is assigned a switching device.

18. The system of claim 17, wherein the control unit of the memory circuit is configured to switch the plurality of switching devices in such a way that the bits of the fixed programmed test data are output to the output terminals in a manner offset with respect to one another.

19. The system of claim 13, wherein the number of fixed programmed test data comprises pseudorandom test data.

20. The system of claim 13, wherein the memory circuit comprises a dynamic random access memory (DRAM) circuit.
